(19) United States
(12) Patent Application Publication
(10) Pub. No.: US 2026/0333886 A1
(43) Pub. Date: Oct. 22, 2026

(54) SOLAR CELL PANEL

(71) Applicant: HANWHA SOLUTIONS CORPORATION, Seoul (KR)

(72) Inventors: Hyeon Seung LEE, Seoul (KR); Soo Yeoun OH, Seoul (KR); Sang Hyuk LEE, Seoul (KR); Ji Su PARK, Seoul (KR); Sung Jin KIM, Seoul (KR); Jin Soo KIM, Seoul (KR); Se Young SEO, Seoul (KR); II Kyo LEE, Seoul (KR); Myeong Kyu KANG, Seoul (KR); Moon Taek LIM, Seoul (KR)

(21) Appl. No.: 19/115,698

(22) PCT Filed: Jun. 13, 2023
(86) PCT No.: PCT/KR2023/008104

§ 371 Date: Mar. 26, 2025

(30) Foreign Application Priority Data
Nov. 3, 2022 (KR) 10-2022-0145355

(51) Int. Cl. H10F 19/90; H10F 77/00; H10F 77/20

(52) U.S. Cl. CPC H10F 19/904; H10F 77/211; H10F 77/935; H10F 77/955

(57) ABSTRACT

A solar cell panel is provided. The solar cell panel according to one aspect of the present disclosure may include: a substrate; an electrode including a first electrode arranged along a first direction on one surface of the substrate and a second electrode arranged parallel to and spaced apart from the first electrode; a wire mounted on the substrate and arranged between the first electrode and the second electrode along the first direction; and a binder connected to the electrode with the wire arranged between components constituting the binder.

### TECHNICAL FIELD

The disclosure relates to solar cells, and more particularly, to a solar cell panel for enhancing solar power generation efficiency.

### BACKGROUND ART

Solar cells constitute principal components for converting light energy into electrical energy in photovoltaic power generation, wherein the photovoltaic power generation has garnered significant interest as a means for addressing climate change attributable to fossil fuel consumption.

While such photovoltaic power generation had higher electricity production costs compared to fossil fuel-based power generation, recent technological advances have led to ongoing research aimed at reducing the electricity production costs of photovoltaic power generation.

Methods for reducing the cost of photovoltaic power generation include improving solar cell power generation efficiency and reducing solar cell manufacturing costs.

One approach for enhancing solar cell power generation efficiency comprises utilizing metals exhibiting superior electrical conductivity as components thereof. However, metals possessing superior electrical conductivity generally result in increased solar cell manufacturing costs.

To solve these problems, there exists a need for solar cells that reduce manufacturing costs while simultaneously improving photovoltaic power generation efficiency through reduction of metal content contained therein.

### DISCLOSURE OF INVENTION

### Technical Problem

The present disclosure provides solutions to these problems, wherein an objective of the present disclosure is to provide a solar cell panel apparatus for enhancing the efficiency of photovoltaic power generation while reducing solar cell manufacturing costs.

The objectives of the present disclosure are not limited to those explicitly set forth herein, and additional objectives will be readily apparent to those having ordinary skill in the relevant art from the following detailed description.

### Technical Solution

According to one aspect of the present disclosure, a solar cell panel is provided, including: a substrate; an electrode including a first electrode arranged along a first direction on one surface of the substrate and a second electrode arranged parallel to and spaced apart from the first electrode; a wire mounted on the substrate and arranged between the first electrode and the second electrode along the first direction; and a binder connected to the electrode with the wire arranged between components constituting the binder.

In some embodiments, the binder may include a first binder connected to the first electrode; a second binder connected to the second electrode; and a third binder connecting the first binder to the second binder.

In some embodiments, the thickness of the first electrode may be equal to the thickness of the second electrode, the thickness of the first binder may be equal to the thickness of the second binder, and the thickness of the first binder may be greater than the thickness of the first electrode.

In some embodiments, the third binder may be spaced apart from one end of the wire.

In some embodiments, the first binder may include: a first electrode connecting portion connected to one end of the first electrode; and a first binder connecting portion connected to the third binder, and the second binder may include: a second electrode connecting portion connected to one end of the second electrode; and a second binder connecting portion connected to the third binder, wherein the first binder connecting portion and the second binder connecting portion may be formed to be inclined.

In some embodiments, the solar cell panel may further include a plurality of solder portions arranged between the first electrode and the second electrode, wherein the wire may be mounted to the substrate through the plurality of solder portions.

In some embodiments, the width of the plurality of solder portions may increase along the first direction.

In some embodiments, the solar cell panel may further include a plurality of connecting portions arranged between the plurality of solder portions and connecting the first electrode and the second electrode.

### Advantageous Effects of Invention

According to the above configuration, in a solar cell panel according to an embodiment of the present disclosure, as the binder is connected to an electrode that produces electricity while placing a wire that transports electrons between components constituting the binder, the efficiency of electricity production is improved.

### BRIEF DESCRIPTION OF DRAWINGS

FIG. 1 is a plan view schematically illustrating a solar cell panel according to an embodiment of the present disclosure.

FIG. 2 is a diagram mainly showing a binder of a solar cell panel according to an embodiment of the present disclosure.

FIG. 3 is a plan view illustrating an appearance of a solar cell panel prior to wire mounting on a substrate according to an embodiment of the present disclosure.

FIG. 4 is a plan view schematically illustrating a solar cell panel according to another embodiment of the present disclosure.

FIG. 5 is a plan view schematically illustrating a solar cell panel according to another embodiment of the present disclosure.

100: Solar cell panel 110: Substrate
120: Electrode 121: First Electrode
122: Second electrode 130: Binder
150: Wire

### MODE FOR CARRYING OUT THE INVENTION

Hereinafter, embodiments of the present disclosure may be described in detail with reference to the accompanying drawings to enable those having ordinary skill in the relevant art to readily implement the present disclosure. The present disclosure may be embodied in various forms and may not be limited to the embodiments described herein. In the drawings, portions not related to the description may be omitted for clarity, and like reference numerals may designate like or similar components throughout the specification.

Words and terms used in the present specification and claims may not be construed as limited to their ordinary or dictionary meanings, but may be interpreted as having meanings and concepts consistent with the technical scope of the present disclosure, based on the principle that an inventor can appropriately define terms to best describe the invention.

Therefore, the embodiments described in the present specification and configurations shown in the drawings may correspond to preferred embodiments of the present disclosure and may not represent all technical aspects of the present disclosure. Accordingly, various equivalents and modifications thereof may be possible at the time of filing of the present disclosure.

In the present specification, terms such as “include” or “have” may be used to indicate the presence of features, numbers, steps, operations, components, parts, or combinations thereof described in the specification, but may not preclude the possibility of presence or addition of one or more other features, numbers, steps, operations, components, parts, or combinations thereof.

When a component may be described as being “in front of,” “behind,” “above,” or “below” another component, unless specifically noted otherwise, such descriptions may include not only direct placement “in front of,” “behind,” “above,” or “below” the other component, but also configurations wherein another component may be interposed therebetween. Furthermore, when a component may be described as being “connected” to another component, such connection may include not only direct connections but also indirect connections, unless specifically noted otherwise.

Hereinafter, a solar cell panel according to an embodiment of the present disclosure may be described with reference to the drawings.

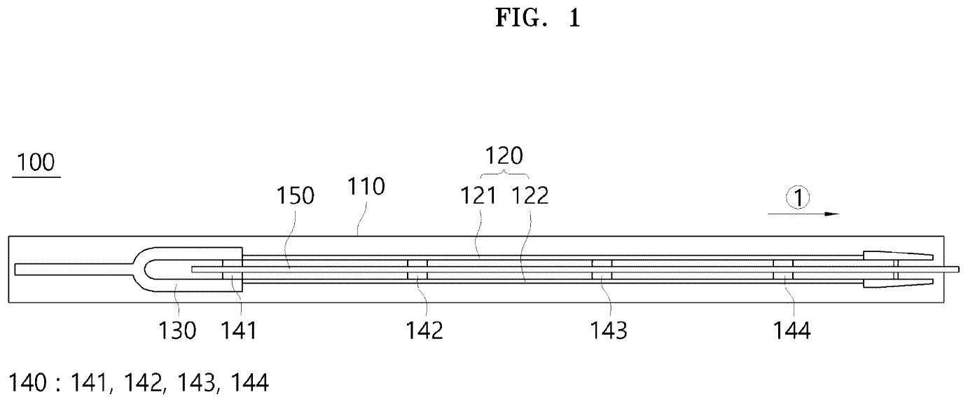

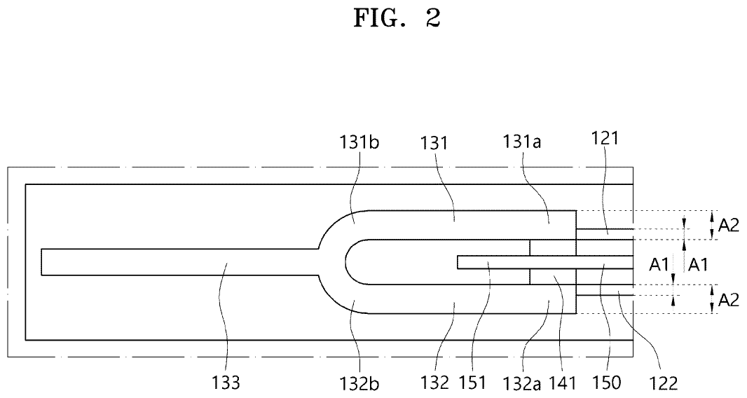

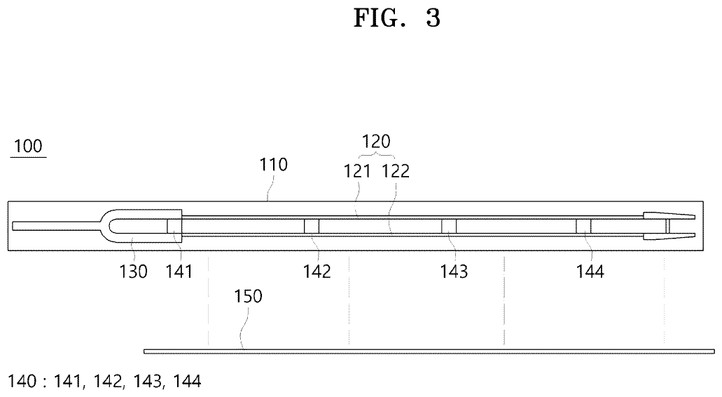

FIG. 1 is a plan view schematically illustrating a solar cell panel according to an embodiment of the present disclosure, FIG. 2 is a diagram mainly showing a binder of a solar cell panel according to an embodiment of the present disclosure, and FIG. 3 is a plan view illustrating an appearance of a solar cell panel prior to wire mounting on a substrate according to an embodiment of the present disclosure.

Referring to FIGS. 1 to 3, a solar cell panel 100 according to an embodiment of the present disclosure may include a substrate 110, an electrode 120, a wire 150, and a binder 130. The front side of the solar cell panel 100 may directly receive sunlight, and the back side of the solar cell panel 100 may receive reflected sunlight.

The substrate 110 may receive sunlight. In some embodiments, the substrate 110 may include a silicon material. However, the substrate 110 may not be limited to including silicon material, and may include various materials having semiconductor properties.

In some embodiments, one side of the substrate 110 may be the back surface of the solar cell panel 100. However, one side of the substrate 110 may not be limited to the back side of the solar cell panel 100, and may be the front side of the solar cell panel 100.

The electrode 120 may be arranged on one surface of the substrate 110. The electrode 120 may include aluminum or an aluminum alloy material. In some embodiments, the electrode 120 may produce electricity from electrons generated from sunlight received by the substrate 110. In some embodiments, the electrode 120 may include a first electrode 121 and a second electrode 122.

The first electrode 121 may be arranged along the first direction \textcircled{1} on one surface of the substrate 110. In some embodiments, as shown in FIG. 2, the first electrode 121 may have a first thickness A1.

The second electrode 122 may be arranged along the first direction \textcircled{1} on one surface of the substrate 110. In some embodiments, the second electrode 122 may be arranged parallel to the first electrode 121 while being spaced apart from the substrate 110. In some embodiments, the second electrode 122 may have a first thickness A1, which is equal to the thickness of the first electrode 121.

The wire 150 may be mounted on the substrate 110. In some embodiments, the wire 150 may be placed along the first direction \textcircled{1} between the first electrode 121 and the second electrode 122. In some embodiments, the wire 150 may include copper or a copper alloy material. However, the wire 150 may not be limited to including copper or copper alloy material, and may include various other metal materials having electrical conductivity.

In some embodiments, the wire 150 may transfer electricity produced by the substrate 110 and the electrode 120. In some embodiments, the wire 150 may be arranged along another surface of the substrate 110 by penetrating the substrate 110 or may be connected to another solar cell panel to transmit electricity.

The binder 130 may be connected to the electrode 120 with the wire 150 between components constituting the binder 130. Since the binder 130 is formed in a form that wraps around the wire 150, electrons generated from the substrate 110 may be smoothly transferred to the wire 150, thereby improving the efficiency of electricity production.

As shown in FIG. 2, the binder 130 may include a first binder 131, a second binder 132, and a third binder 133.

The first binder 131 may be connected to the first electrode 121. some embodiments, the first binder 131 may have a second thickness A2. In some embodiments, the second thickness A2 may be greater than the first thickness A1.

The second binder 132 may be connected to the second electrode 122. In some embodiments, the second binder 132 may have the second thickness A2 which may be the same as the thickness of the first binder 131.

As the first binder 131 and the second binder 132 may each wrap around one end of the wire 150 and may have the second thickness A2 greater than the first thickness A1, electrons generated from the substrate 110 may be smoothly transferred to one end of the wire 150, thereby improving the efficiency of electricity production.

The third binder 133 may connect the first binder 131 and the second binder 132. In some embodiments, The third binder 133 may be spaced apart from one end of the wire 150.

In some embodiments, the first binder 131 may include a first electrode connecting portion 131a connected to one end of the first electrode 121 and a first binder connecting portion 131b connected to the third binder 133.

In some embodiments, the second binder 132 may include a second electrode connection portion 132a connected to one end of the second electrode 122 and a second binder connection portion 132b connected to the third binder 133.

In some embodiments, the first binder connecting portion 131a and the second binder connecting portion 132a may be formed at an angle. Accordingly, the first binder connecting portion 131a and the second binder connecting portion 132a may minimize the path through which the first binder 131 and the second binder 132 are connected to the third binder 133, while minimizing changes in electrical characteristics due to the connection of the first binder 131 and the second binder 132 to the third binder 133.

In some embodiments, the third binder 133 may be connected to the first binder 131 and the second binder 132 and may wrap around one end of the wire 150, so that electrons generated from the substrate 110 may be smoothly transferred to one end of the wire 150, thereby improving the efficiency of electricity production.

In some embodiments, the third binder 133 may be connected to the first binder 131 and the second binder 132 to minimize blocking of one side of the substrate 110 from the outside, so that the substrate 110 may stably secure an area where the substrate 110 receives sunlight.

In some embodiments, a solar cell panel 100 according to an embodiment of the present disclosure may be provided with a plurality of solder portions 140 arranged between the first electrode 121 and the second electrode 122.

The plurality of solder portions 140 may be arranged spaced apart from each other along the first direction \textcircled{1}. In some embodiments, the plurality of solder portions 140 may include silver (Ag) material. However, the plurality of solder portions 140 may not be limited to including silver (Ag) material.

In some embodiments, the plurality of solder portions 140 may be combined with the wire 150 by heat. In some embodiments, the wire 150 may be mounted on the substrate 110 through the plurality of solder portions 140. In some embodiments, the plurality of solder portions 140 may include a first solder portion 141, a second solder portion 142, a third solder portion 143, and a fourth solder portion 144.

The first solder portion 141 may be placed between the first binder 131 and the second binder 132. In some embodiments, the second solder portion 142 may be spaced apart from the first solder portion 141. In some embodiments, the third solder portion 143 may be spaced apart from the second solder portion 142. In some embodiments, the fourth solder portion 144 may be spaced apart from the third solder portion 143.

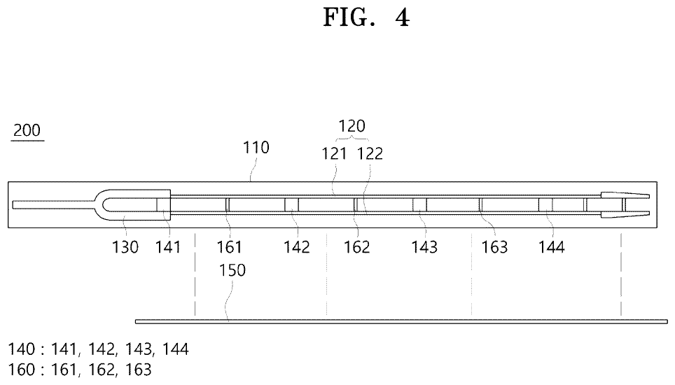

FIG. 4 is a plan view schematically illustrating a solar cell panel according to another embodiment of the present disclosure.

Referring to FIG. 4, a solar cell panel 200 according to another embodiment of the present disclosure may include components of the previously described embodiment and a plurality of connecting portions 160, and descriptions of components identical or similar to those of the previously described embodiment of the present disclosure are replaced with the previously described description, and the plurality of connecting portions 160 may be mainly described.

The plurality of connecting portions 160 may connect the first electrode 121 and the second electrode 122 to each other. In some embodiments, the plurality of connecting portions 160 may be arranged at a certain interval from the plurality of solder portions 140.

In some embodiments, the plurality of connecting portions 160 may include the same material as the electrode 120. For example, the plurality of connecting portions 160 may include aluminum or an aluminum alloy material. In some embodiments, the plurality of connecting portions 160 may include a first connecting portion 161, a second connecting portion 162, and a third connecting portion 163.

The first connecting portion 161 may be placed between the first solder portion 141 and the second solder portion 142. In some embodiments, as the first connecting portion 161 intersects with the wire 150, electrons of the substrate 110 may be smoothly transferred to the wire 150.

The second connecting portion 162 may be positioned between the second solder portion 142 and the third solder portion 143. In some embodiments, as the second connecting portion 162 intersects with the wire 150, electrons of the substrate 110 may be smoothly transferred to the wire 150.

The third connecting portion 163 may be positioned between the third solder portion 143 and the fourth solder portion 144. In some embodiments, as the third connecting portion 163 intersects with the wire 150, electrons of the substrate 110 may be smoothly transferred to the wire 150.

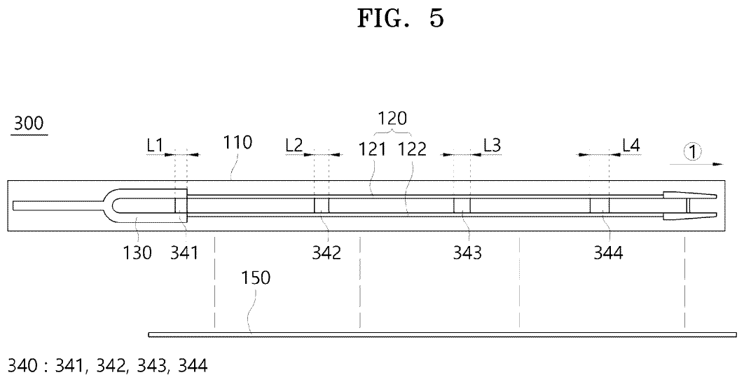

FIG. 5 is a plan view schematically illustrating a solar cell panel according to another embodiment of the present disclosure.

Referring to FIG. 5, a solar cell panel 300 according to another embodiment of the present disclosure may include components identical or similar to those of the previously described embodiment, and the descriptions of components identical or similar to those of the previously described embodiment of the present disclosure are replaced with the previously described description, and a plurality of solder portions 340 may be mainly described.

The width of the plurality of solder portions 340 may increase along the first direction \textcircled{1}. In some embodiments, the plurality of solder portions 340 may include a first solder portion 341, a second solder portion 342, a third solder portion 343, and a fourth solder portion 344.

The first solder portion 341 may have a first width L1. In some embodiments, the second solder portion 342 may have a second width L2 that is larger than the first width L1. In some embodiments, the third solder portion 343 may have a third width L3 that is larger than the second width L2. In some embodiments, the fourth solder portion 344 may have a fourth width L4 that is larger than the third width L3.

In some embodiments, one end of the wire 150 may penetrate the substrate 110 in an area adjacent to the binder 130. In some embodiments, another end of the wire 150 may be connected to another solar cell panel (not shown).

In some embodiments, during mounting of the wire 150 to the substrate 110 through the plurality of solder portions 340, shaking may occur along the first direction \textcircled{1}, which may cause misalignment of the wire 150 relative to the first direction \textcircled{1}.

To solve this problem, as the width of the plurality of solder portions 340 may increase along the first direction \textcircled{1}, the contact area of the wire 150 may be increased, so that the wire 150 may be stably mounted to the substrate 110.

Although embodiments of the present disclosure have been described, the concept of the present disclosure may not be limited to the embodiments presented in this specification, and those skilled in the art who understand the spirit of the present disclosure may be able to easily propose other embodiments by adding, changing, deleting, or adding components within the scope of the same spirit, but this may also be considered to fall within the spirit of the present disclosure.

1. A solar cell panel comprising:
a substrate;
an electrode including a first electrode arranged along a first direction on one surface of the substrate and a second electrode arranged parallel to and spaced apart from the first electrode;
a wire mounted on the substrate and arranged along the first direction between the first electrode and the second electrode; and
a binder connected to the electrode with the wire arranged between components constituting the binder.

2. The solar cell panel of claim 1, wherein
the binder comprises:
a first binder connected to the first electrode;
a second binder connected to the second electrode; and
a third binder connecting the first binder to the second binder.

3. The solar cell panel of claim 2, wherein:
a thickness of the first electrode is equal to a thickness of the second electrode,
the thickness of the first binder is equal to the thickness of the second binder, and
the thickness of the first binder is greater than the thickness of the first electrode.

4. The solar cell panel of claim 2, wherein
the third binder is arranged spaced apart from one end of the wire.

5. The solar cell panel of claim 2, wherein
the first binder comprises:
a first electrode connecting portion connected to one end of the first electrode; and
a first binder connecting portion connected to the third binder, and
the second binder comprises:
a second electrode connecting portion connected to one end of the second electrode; and
a second binder connecting portion connected to the third binder, wherein the first binder connecting portion and the second binder connecting portion are each formed to be inclined.

6. The solar cell panel of claim 1, further comprising:
a plurality of solder portions arranged between the first electrode and the second electrode, wherein
the wire is mounted to the substrate through the plurality of solder portions.

7. The solar cell panel of claim 6, wherein
the width of the plurality of solder portions increases along the first direction.

8. The solar cell panel of claim 6, further comprising
a plurality of connecting portions arranged between the plurality of solder portions and connecting the first electrode to the second electrode.
